(19) United States
(12) Patent Application Publication
(10) Pub. No.: US 2008/0204538 A1
(43) Pub. Date: Aug. 28, 2008

(54) PRINTING ON CORRUGATED SUBSTRATES

(75) Inventors: Gregory Joseph Kovacs, Webster, NY (US); Steven E. Ready, Los Altos, CA (US); Jennifer L. Belelie, Oakville (CA); Peter Gordon Odell, Mississauga (CA); Mojgan Rabbani, Pittsford, NY (US); Shriram V. Revankar, Webster, NY (US)

Correspondence Address: FAY SHARPE / XEROX - ROCHESTER, 1100 SUPERIOR AVE., SUITE 700, CLEVELAND, OH, 44114, US

(73) Assignee: XEROX CORPORATION, Norwalk, CT (US)

(21) Appl. No.: 12/107,520

(22) Filed: Apr. 22, 2008

Related U.S. Application Data
(63) Continuation-in-part of application No. 11/427,172, filed on Jun. 28, 2006.

(51) Int. Cl. B41J 2/01; C23C 14/28

(52) U.S. Cl. 347/102; 427/595

(57) ABSTRACT

Methods and devices for forming, such as by printing, high quality, high throughput, ultraviolet curable gel ink images on corrugated substrates for packaging applications are disclosed. The methods and devices have excellent edge acuity and do not require precoating of the substrate prior to printing or nitrogen inerting during curing.

### CROSS-REFERENCE TO RELATED APPLICATIONS

This application is a continuation-in-part application of U.S. patent application Ser. No. 11/427,172, filed Jun. 28, 2006. This application is also related to U.S. patent application Ser. No. 11/290,121, filed Nov. 30, 2005; and U.S. patent application Ser. No. 11/290,202, filed Nov. 30, 2005. All three of these applications are hereby fully incorporated herein by reference.

### BACKGROUND

The present disclosure generally relates to methods and devices for forming images on corrugated substrates. In this regard, this disclosure relates to forming or printing images on corrugated surfaces such as those used in packaging and other applications, through the use of curable phase change inks.

Conventional ink jet printing systems, such as drop-on-demand or continuous systems, are known in the art. In drop-on-demand systems, a droplet is expelled from the orifice of a printhead directly to a position on a recording medium, such as paper. A droplet is not formed or expelled unless it is to be placed on the recording medium.

An example of such a drop-on-demand system is known as thermal ink jet (TIJ), or bubble jet. It produces high velocity droplets by passing a current pulse through a resistive layer within the ink passageway near the nozzle, causing the ink vehicle in the immediate vicinity to vaporize and expel droplets of ink from the nozzle.

Another example of a drop-on-demand system is piezoelectric ink jet (PIJ). In such a system, the printhead has as its major components an ink filled channel or passageway having a nozzle on one end and a piezoelectric transducer near the other end. The piezoelectric transducer produces pressure pulses which expel drops of ink from the nozzle.

A further example of a drop-on-demand system is known as acoustic ink printing. As is known, an acoustic beam exerts a radiation pressure against objects upon which it impinges. Thus, when an acoustic beam impinges on a free surface (i.e., liquid/air interface) of a pool of liquid from beneath, the acoustic pressure which it exerts against the surface of the pool may reach a sufficiently high level to release individual droplets of liquid from the pool, despite the restraining force of surface tension. Focusing the beam on or near the surface of the pool intensifies the acoustic pressure it exerts for a given amount of input power.

Printing on corrugated substrates may be useful for various applications. The term “corrugated” is intended to refer to corrugated materials such as cardboard, which may be used for producing boxes, etc. Cardboard is a sheet-like product formed by a corrugated member glued or fixed to, or between, one or more relatively flat facing members. The corrugated member has a design of alternating ridges and valleys manufactured to a specific pitch. The liner or top surface of the cardboard is generally kraft paper, which is made from coarse brown-colored wood pulp. If the liner is intended for printing of high quality color graphics, the liner will usually be made from either kraft paper which is bleached white and given a matte finish, or from a coated paper having a glossy finish.

Currently, many applications of digital printing on corrugated substrates use aqueous TIJ inks to print directly onto kraft paper (either brown-colored kraft or bleached white kraft). These inks may produce poor image quality because they bleed into the substrate and along the coarse fibers in the corrugated surface. Such images are acceptable for certain monochrome applications, such as case coding of images printed to facilitate shipping, handling, and inventory management. However, they are not very acceptable for color graphics applications. Such color images may be distorted or blurred, resulting in a loss of information and especially in loss of image quality. In addition, it is difficult to print high quality color graphics directly onto an unbleached brown corrugated liner. A white liner is preferred for high quality color rendition because a brown base will cause the printed colors to have an unnatural looking hue shift compared to colors printed on a white base.

Alternatively, color images may be imprinted onto corrugated substrates using press-type transfer printing plates. These printing plates are flat plates or rolls which are engraved with the desired image, then coated with an ink of the appropriate color, and pressed onto the corrugated substrate. However, this type of printing is generally only suitable for static color images. In particular, this type is not suitable for printing variable data (such as unique images in each impression) or small production runs, because of the large cost and change-over time required for preparing and mounting a new printing plate whenever a new or different image is required (i.e., it is not economically efficient nor time efficient).

Sun Chemical and Inca Digital have jointly produced a FastJet™ Press that prints color images on a corrugated substrate. However, a pretreatment with aqueous UV primer is required to seal the corrugated surface prior to printing in order to control ink wetting and prevent ink bleeding. Nitrogen inertion is also required during curing to enable a fast cure and high throughput. These further requirements increase the total cost of the printed corrugated substrate.

Additional means that allow for forming images or printing on corrugated substrates are still desired.

### BRIEF DESCRIPTION

The present application discloses, in various exemplary embodiments, devices and processes for forming or printing images, such as color images, on corrugated substrates. Among other characteristics, the resulting images have good edge acuity. Methods of making and using such images are also disclosed.

In embodiments, a method for forming an image on a corrugated substrate comprises:

melting a radiation-curable gel based phase change ink;

depositing at least one drop of the melted ink on the corrugated substrate in a pattern to form an image;

allowing the ink to solidify or gel on the substrate; and

curing the ink.

The ink may be cured in an ambient atmosphere. Alternatively, the ink may be cured by exposing the ink to ultraviolet light. Additionally, the ink may be heated and melted until the ink has a viscosity of from about 5 to about 15 millipascal-seconds, or to a temperature of from about 70° C. to about 95° C. The radiation-curable gel based phase change ink may be comprised of an ink vehicle that includes at least one curable monomer, at least one phase change agent, a colorant, and optionally a photoinitiator.

In some embodiments, the corrugated substrate is not treated or pretreated with ultraviolet-curable-ink primer prior to depositing the at least one drop of the ink.

The image may have an edge raggedness, as measured using the PIAS IQ measurement system, of 0.02 or less.

In other embodiments, a method for forming an image on a corrugated substrate comprises:

heating an ultraviolet-curable gel based phase change ink to form a liquid;

depositing one or more drops of the liquid ink onto a corrugated substrate in an imagewise pattern;

allowing the liquid ink of the imagewise pattern to solidify to form a gel; and

curing the ultraviolet-curable gel ink.

In other embodiments, an ultraviolet-curable gel ink printing system comprises:

at least one heat source configured to heat or melt an ultraviolet-curable gel based phase change ink;

at least one printhead configured to deposit droplets of the melted ink in an imagewise pattern onto an associated corrugated substrate; and

an ultraviolet light source configured to cure the ink after the ink is deposited on the associated corrugated substrate and allowed to gel.

The ultraviolet light source may be located in a curing zone absent an inert atmosphere.

In some embodiments, the system is not configured to deposit, pretreat, or precoat a primer on the associated substrate prior to depositing the ink.

The at least one printhead may be a piezoelectric printhead.

The system may be configured to fully cure the ink at throughput speeds of 200 feet per minute or greater.

These and other non-limiting characteristics of the disclosure are more particularly disclosed below.

### BRIEF DESCRIPTION OF THE FIGURES

The patent or application file contains at least one drawing executed in color. Copies of this patent or patent application publication with color drawing(s) will be provided by the Office upon request and payment of the necessary fee.

The following is a brief description of the drawings, which are presented here for purposes of illustrating various aspects of embodiments of the present disclosure and not to be limiting features thereof.

FIG. 1 is one embodiment of a printing system of the present disclosure.

FIG. 2 is a color photograph showing an 8 pt text character printed from a UV gel ink printing system on brown corrugated cardboard.

FIG. 3 is a color photograph showing an 8 pixel wide line printed at 600 dpi from a UV gel ink printing system on brown corrugated cardboard.

FIG. 4 is a color photograph showing the edge of a solid area printed from a UV gel ink printing system on brown corrugated cardboard.

FIG. 5 is a digitally manipulated enhancement of FIG. 2 with high contrast.

FIG. 6 is a digitally manipulated enhancement of FIG. 3 with high contrast.

FIG. 7 is a digitally manipulated enhancement of FIG. 4 with high contrast.

FIG. 8 is a color photograph showing an 8 pt text character printed from a UV gel ink printing system on white corrugated cardboard.

FIG. 9 is a color photograph showing an 8 pixel wide line printed at 600 dpi from a UV gel ink printing system on white corrugated cardboard.

FIG. 10 is a color photograph showing the edge of a solid area printed from a UV gel ink printing system on white corrugated cardboard.

FIG. 11 is a color photograph showing an 8 pt text character printed from a UV gel ink printing system on super glossy paper.

FIG. 12 is a color photograph showing an 8 pixel wide line printed at 600 dpi from a UV gel ink printing system on super glossy paper.

FIG. 13 is a color photograph showing the edge of a solid area printed from a UV gel ink printing system on super glossy paper.

FIG. 14 is a color photograph showing an 8 pt text character printed from a UV gel ink printing system on a transparent sheet.

FIG. 15 is a color photograph showing an 8 pixel wide line printed at 600 dpi from a UV gel ink printing system on a transparent sheet.

FIG. 16 is a color photograph showing the edge of a solid area printed from a UV gel ink printing system on a transparent sheet.

FIG. 17 is a color photograph showing an 8 pt text character printed from a UV gel ink printing system on plain office paper (75 gsm).

FIG. 18 is a color photograph showing an 8 pixel wide line printed at 600 dpi from a UV gel ink printing system on plain office paper (75 gsm).

FIG. 19 is a color photograph showing the edge of a solid area printed from a UV gel ink printing system on plain office paper (75 gsm).

FIG. 20 is a color photograph showing an 8 pt text character printed from a first aqueous ink printing system on plain office paper (60 gsm).

FIG. 21 is a color photograph showing an 8 pixel wide line printed at 600 dpi from a first aqueous ink printing system on plain office paper (60 gsm).

FIG. 22 is a color photograph showing the edge of a solid area printed from a first aqueous ink printing system on plain office paper (60 gsm).

FIG. 23 is a color photograph showing an 8 pt text character printed from a second aqueous ink printing system on plain office paper (60 gsm).

FIG. 24 is a color photograph showing an 8 pixel wide line printed at 600 dpi from a second aqueous ink printing system on plain office paper (60 gsm).

FIG. 25 is a color photograph showing the edge of a solid area printed from a second aqueous ink printing system on plain office paper (60 gsm).

FIG. 26 is a color photograph showing an 8 pt text character printed from a solid wax ink printing system on plain office paper (75 gsm).

FIG. 27 is a color photograph showing an 8 pixel wide line printed at 563 dpi from a solid wax ink printing system on plain office paper (75 gsm)

FIG. 28 is a color photograph showing the edge of a solid area printed from a solid wax ink printing system on plain office paper (75 gsm).

FIG. 29 is a color photograph showing an 8 pt text character printed from a laser printer system on plain office paper (75 gsm).

FIG. 30 is a color photograph showing an 8 pixel wide line printed at 600 dpi from a laser printer system on plain office paper (75 gsm).

FIG. 31 is a color photograph showing the edge of a solid area printed from a laser printer system on plain office paper (75 gsm).

### DETAILED DESCRIPTION

High image quality in inkjet printing onto corrugated substrates, such as corrugated cardboard, can be significantly improved by the use of radiation curable gel based phase change inks. Phase change inks, also known as hot-melt inks, are generally solid at ambient temperatures, but liquid at elevated temperatures. Phase change inks are desirable for ink jet printers because they remain in a solid phase at room temperature during shipping, long term storage, and the like. In addition, the problems associated with nozzle clogging as a result of ink evaporation with liquid ink jet inks are largely eliminated, thereby improving the reliability of the ink jet printing. Further, when phase change ink droplets are applied directly onto the corrugated substrate, the droplets solidify immediately upon contact with the substrate, so that migration of ink on the substrate is prevented and dot quality is improved.

The phrase “gel-based” refers to a property of some phase change inks in that they undergo a sharp increase in viscosity over a narrow temperature range above room temperature, and freeze to a gel-like consistency which is retained as the inks are cooled further to room temperature. For example, some phase change inks which may be suitable for use in the devices and methods of the present disclosure have a viscosity which changes by a factor of 10⁴ to 10⁹ over a temperature change of only about 20 to about 40 degrees Celsius.

The phrase “radiation curable” refers to the ability of the phase change ink to be cured so that it becomes permanently fixed to the corrugated substrate. All forms of curing upon exposure to a radiation source are contemplated, including light and heat sources in the presence or absence of initiators, Exemplary radiation curing routes include, but are not limited to, curing using ultraviolet (UV) light, for example having a wavelength of 200-400 nm, or more rarely using visible light, curing using e-beam radiation, curing using thermal curing, and appropriate combinations thereof.

Radiation curable gel based phase change inks generally comprise at least one curable monomer, at least one phase change agent, and a colorant. They may further comprise at least one photoinitiator that initiates polymerization of the curable monomer. Exemplary phase change inks suitable for use include those described in U.S. Pat. Nos. 7,276,614 and 7,279,587 and U.S. Patent Publication Nos. 2007/0120908; 2007/0120909; and 2007/0120925, the entire disclosures of which are hereby fully incorporated herein by reference. The printing processes of the present disclosure take advantage of this rapid change in the viscosity to minimize ink bleed along the fibers of the corrugated liner surface prior to curing.

The curing of the curable monomer may be radically or cationically initiated. In embodiments, the monomer is equipped with one or more curable moieties, including, but not limited to, acrylates; methacrylates; vinyl ethers; epoxides, such as cycloaliphatic epoxides, aliphatic epoxides, and glycidyl epoxides; oxetanes; and the like. Suitable radiation, such as UV, curable monomers include, but are not limited to, acrylated esters, acrylated polyesters, acrylated ethers, acrylated polyethers, acrylated epoxies, urethane acrylates, and pentaerythritol tetraacrylate. Specific examples of suitable acrylated monomers include monoacrylates, diacrylates, and polyfunctional alkoxylated or polyalkoxylated acrylic monomers comprising one or more di- or tri-acrylates. Suitable monoacrylates are, for example, cyclohexyl acrylate, 2-ethoxy ethyl acrylate, 2-methoxy ethyl acrylate, 2-(2-ethoxyethoxy)ethyl acrylate, stearyl acrylate, tetrahydrofurfuryl acrylate, octyl acrylate, lauryl acrylate, behenyl acrylate, 2-phenoxy ethyl acrylate, tertiary butyl acrylate, glycidyl acrylate, isodecyl acrylate, benzyl acrylate, hexyl acrylate, isooctyl acrylate, isobornyl acrylate, butanediol monoacrylate, ethoxylated phenol monoacrylate, oxyethylated phenol acrylate, monomethoxy hexanediol acrylate, beta-carboxy ethyl acrylate, dicyclopentyl acrylate, carbonyl acrylate, octyl decyl acrylate, ethoxylated nonylphenol acrylate, hydroxyethyl acrylate, hydroxyethyl methacrylate, and the like. Suitable polyfunctional alkoxylated or polyalkoxylated acrylates are, for example, alkoxylated, such as ethoxylated or propoxylated, variants of the following neopentyl glycol diacrylates, butanediol diacrylates, trimethylolpropane triacrylates, glyceryl triacrylates, 1,3-butylene glycol diacrylate, 1,4-butanediol diacrylate, diethylene glycol diacrylate, 1,6-hexanediol diacrylate, tetraethylene glycol diacrylate, triethylene glycol diacrylate, tripropylene glycol diacrylate, polybutanediol diacrylate, polyethylene glycol diacrylate, propoxylated neopentyl glycol diacrylate, ethoxylated neopentyl glycol diacrylate, polybutadiene diacrylate, and the like. In embodiments, one suitable monomer is a propoxylated neopentyl glycol diacrylate, such as, for example, SR-9003 (Sartomer Co., Inc., Exton, Pa.). Other suitable reactive monomers are likewise commercially available from, for example, Sartomer Co., Inc., Henkel Corp., Radcure Specialties, and the like.

The curable monomer in embodiments is included in the ink in an amount of, for example, about 20 to about 90% by weight of the ink, such as about 30 to about 85% by weight of the ink, or about 40 to about 80% by weight of the ink.

The phase change agent may generally be any component that is miscible with the other components of the phase change ink and promotes the increase in viscosity of the ink as it cools from the jetting temperature to the substrate temperature. Examples of classes of phase change agents include gellants, solid alcohols, and waxes.

In specific embodiments, a gellant is used as the phase change agent. The organic gellant functions to dramatically increase the viscosity of the ink within a desired temperature range. In particular, the gellant forms a semi-solid gel in the ink vehicle at temperatures below the specific temperature at which the ink is jetted. The semi-solid gel phase is a physical gel that exists as a dynamic equilibrium comprised of one or more solid gellant molecules and a liquid solvent. The semi-solid gel phase is a dynamic networked assembly of molecular components held together by non-covalent interactions such as hydrogen bonding, Van der Waals interactions, aromatic non-bonding interactions, ionic or coordination bonding, London dispersion forces, and the like, which upon stimulation by physical forces such as temperature and mechanical agitation or chemical forces such as pH or ionic strength, can reversibly transition from liquid to semi-solid state at the macroscopic level. The inks exhibit a thermally reversible transition between the semi-solid gel state and the liquid state when the temperature is varied above or below the gel point of the ink. This reversible cycle of transitioning between semi-solid gel phase and liquid phase can be repeated many times in the ink formulation.

Any suitable gellant can be used for the ink vehicles disclosed herein. Specifically, the gellant can be selected from materials disclosed in U.S. Pat. No. 7,279,687, entitled “Photoinitiator With Phase Change Properties and Gellant Affinity,” with the named inventors Peter G. Odell, Eniko Toma, and Jennifer L. Belelie and U.S. Pat. No. 7,276,614, entitled “Curable Amide Gellant Compounds,” with the named inventors Eniko Toma, Peter G. Odell, Adela Goredema and Jennifer L. Belelie, the disclosures of which are totally incorporated herein by reference, such as a compound of the formula

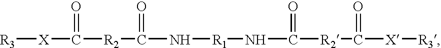

wherein:

### R₁ is:

(i) an alkylene group (wherein an alkylene group is defined as a divalent aliphatic group or alkyl group, including linear and branched, saturated and unsaturated, cyclic and acyclic, and substituted and unsubstituted alkylene groups, and wherein heteroatoms, such as oxygen, nitrogen, sulfur, silicon, phosphorus, boron, and the like either may or may not be present in the alkylene group), in one embodiment with at least 1 carbon atom, and in one embodiment with no more than about 12 carbon atoms, in another embodiment with no more than about 4 carbon atoms, and in yet another embodiment with no more than about 2 carbon atoms, although the number of carbon atoms can be outside of these ranges,

(ii) an arylene group (wherein an arylene group is defined as a divalent aromatic group or aryl group, including substituted and unsubstituted arylene groups, and wherein heteroatoms, such as oxygen, nitrogen, sulfur, silicon, phosphorus, boron, and the like either may or may not be present in the arylene group), in one embodiment with at least about 5 carbon atoms, and in another embodiment with at least about 6 carbon atoms, and in one embodiment with no more than about 14 carbon atoms, in another embodiment with no more than about 10 carbon atoms, and in yet another embodiment with no more than about 6 carbon atoms, although the number of carbon atoms can be outside of these ranges,

(iii) an arylalkylene group (wherein an arylalkylene group is defined as a divalent arylalkyl group, including substituted and unsubstituted arylalkylene groups, wherein the alkyl portion of the arylalkylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the arylalkylene group), in one embodiment with at least about 6 carbon atoms, and in another embodiment with at least about 7 carbon atoms, and in one embodiment with no more than about 32 carbon atoms, in another embodiment with no more than about 22 carbon atoms, and in yet another embodiment with no more than about 7 carbon atoms, although the number of carbon atoms can be outside of these ranges, or

(iv) an alkylarylene group (wherein an alkylarylene group is defined as a divalent alkylaryl group, including substituted and unsubstituted alkylarylene groups, wherein the alkyl portion of the alkylarylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the alkylarylene group), in one embodiment with at least about 6 carbon atoms, and in another embodiment with at least about 7 carbon atoms, and in one embodiment with no more than about 32 carbon atoms, in another embodiment with no more than about 22 carbon atoms, and in yet another embodiment with no more than about 7 carbon atoms, although the number of carbon atoms can be outside of these ranges, wherein the substituents on the substituted alkylene, arylene, arylalkylene, and alkylarylene groups can be (but are not limited to) halogen atoms, cyano groups, pyridine groups, pyridinium groups, ether groups, aldehyde groups, ketone groups, ester groups, amide groups, carbonyl groups, thiocarbonyl groups, sulfide groups, nitro groups, nitroso groups, acyl groups, azo groups, urethane groups, urea groups, mixtures thereof, and the like, wherein two or more substituents can be joined together to form a ring;

R₂ and R′₂each, independently of the other, are selected from the group consisting of:

(i) alkylene groups (wherein an alkylene group is defined as a divalent aliphatic group or alkyl group, including linear and branched, saturated and unsaturated, cyclic and acyclic, and substituted and unsubstituted alkylene groups, and wherein heteroatoms, such as oxygen, nitrogen, sulfur, silicon, phosphorus, boron, and the like either may or may not be present in the alkylene group), in one embodiment with at least 1 carbon atom, and in one embodiment with no more than about 54 carbon atoms, and in another embodiment with no more than about 36 carbon atoms, although the number of carbon atoms can be outside of these ranges,

(ii) arylene groups (wherein an arylene group is defined as a divalent aromatic group or aryl group, including substituted and unsubstituted arylene groups, and wherein heteroatoms, such as oxygen, nitrogen, sulfur, silicon, phosphorus, boron, and the like either may or may not be present in the aryiene group), in one embodiment with at least about 5 carbon atoms, and in another embodiment with at least about 6 carbon atoms, and in one embodiment with no more than about 14 carbon atoms, in another embodiment with no more than about 10 carbon atoms, and in yet another embodiment with no more than about 7 carbon atoms, although the number of carbon atoms can be outside of these ranges,

(iii) arylalkylene groups (wherein an arylalkylene group is defined as a divalent arylalkyl group, including substituted and unsubstituted arylalkylene groups, wherein the alkyl portion of the arylalkylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the arylalkylene group), in one embodiment with at least about 6 carbon atoms, and in another embodiment with at least about 7 carbon atoms, and in one embodiment with no more than about 32 carbon atoms, in another embodiment with no more than about 22 carbon atoms, and in yet another embodiment with no more than about 8 carbon atoms, although the number of carbon atoms can be outside of these ranges, or

(iv) alkylarylene groups (wherein an alkylarylene group is defined as a divalent alkylaryl group, including substituted and unsubstituted alkylarylene groups, wherein the alkyl portion of the alkylarylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the alkylarylene group), in one embodiment with at least about 6 carbon atoms, and in another embodiment with at least about 7 carbon atoms, and in one embodiment with no more than about 32 carbon atoms, in another embodiment with no more than about 22 carbon atoms, and in yet another embodiment with no more than about 7 carbon atoms, although the number of carbon atoms can be outside of these ranges, wherein the substituents on the substituted alkylene, arylene, arylalkylene, and alkylarylene groups can be (but are not limited to) halogen atoms, cyano groups, ether groups, aldehyde groups, ketone groups, ester groups, amide groups, carbonyl groups, thiocarbonyl groups, phosphine groups, phosphonium groups, phosphate groups, nitrile groups, mercapto groups, nitro groups, nitroso groups, acyl groups, acid anhydride groups, azide groups, azo groups, cyanato groups, urethane groups, urea groups, mixtures thereof, and the like, wherein two or more substituents can be joined together to form a ring;

R₃ and R′₃ each, independently of the other, are either:

(i) photoinitiating groups, such as groups derived from 1-(4-(2-hydroxyethoxy)phenyl)-2-hydroxy-2-methylpropan-1-one, of the formula

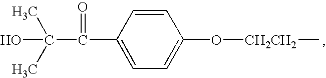

groups derived from 1-hydroxycyclohexylphenylketone, of the formula

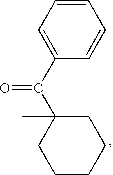

groups derived from 2-hydroxy-2-methyl-1-phenylpropan-1-one, of the formula

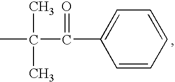

or the like, or:

(ii) a group which is:
(a) an alkyl group (including linear and branched, saturated and unsaturated, cyclic and acyclic, and substituted and unsubstituted alkyl groups, and wherein heteroatoms, such as oxygen, nitrogen, sulfur, silicon, phosphorus, boron, and the like either may or may not be present in the alkyl group), in one embodiment with at least about 2 carbon atoms, in another embodiment with at least about 3 carbon atoms, and in yet another embodiment with at least about 4 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges,
(b) an aryl group (including substituted and unsubstituted aryl groups, and wherein heteroatoms, such as oxygen, nitrogen, sulfur, silicon, phosphorus, boron, and the like either may or may not be present in the aryl group), in one embodiment with at least about 5 carbon atoms, and in another embodiment with at least about 6 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges, such as phenyl or the like,
(c) an arylalkyl group (including substituted and unsubstituted arylalkyl groups, wherein the alkyl portion of the arylalkyl group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the arylalkyl group), in one embodiment with at least about 6 carbon atoms, and in another embodiment with at least about 7 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges, such as benzyl or the like, or
(d) an alkylaryl group (including substituted and unsubstituted alkylaryl groups, wherein the alkyl portion of the alkylaryl group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the alkylaryl group), in one embodiment with at least about 6 carbon atoms, and in another embodiment with at least about 7 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges, such as tolyl or the like, wherein the substituents on the substituted alkyl, arylalkyl, and alkylaryl groups can be (but are not limited to) halogen atoms, ether groups, aldehyde groups, ketone groups, ester groups, amide groups, carbonyl groups, thiocarbonyl groups, sulfate groups, sulfonate groups, sulfonic acid groups, sulfide groups, sulfoxide groups, phosphine groups, phosphonium groups, phosphate groups, nitrile groups, mercapto groups, nitro groups, nitroso groups, sulfone groups, acyl groups, acid anhydride groups, azide groups, azo groups, cyanato groups, isocyanato groups, thiocyanato groups, isothiocyanato groups, carboxylate groups, carboxylic acid groups, urethane groups, urea groups, mixtures thereof, and the like, wherein two or more substituents can be joined together to form a ring;
   X and X′ each, independently of the other, is an oxygen atom or a group of the formula —NR₄—, wherein R₄ is:

(i) a hydrogen atom;

(ii) an alkyl group, including linear and branched, saturated and unsaturated, cyclic and acyclic, and substituted and unsubstituted alkyl groups, and wherein heteroatoms either may or may not be present in the alkyl group, in one embodiment with at least 1 carbon atom, and in one embodiment with no more than about 100 carbon atoms, in another embodiment with no more than about 60 carbon atoms, and in yet another embodiment with no more than about 30 carbon atoms, although the number of carbon atoms can be outside of these ranges,

(iii) an aryl group, including substituted and unsubstituted aryl groups, and wherein heteroatoms either may or may not be present in the aryl group, in one embodiment with at least about 5 carbon atoms, and in another embodiment with at least about 6 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges,

(iv) an arylalkyl group, including substituted and unsubstituted arylalkyl groups, wherein the alkyl portion of the arylalkyl group can be linear or branched, saturated or unsaturated, and cyclic or acyclic, and wherein heteroatoms either may or may not be present in either the aryl or the alkyl portion of the arylalkyl group, in one embodiment with at least about 6 carbon atoms, and in another embodiment with at least about 7 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges, or

(v) an alkylaryl group, including substituted and unsubstituted alkylaryl groups, wherein the alkyl portion of the alkylaryl group can be linear or branched, saturated or unsaturated, and cyclic or acyclic, and wherein heteroatoms either may or may not be present in either the aryl or the alkyl portion of the alkylaryl group, in one embodiment with at least about 6 carbon atoms, and in another embodiment with at least about 7 carbon atoms, and in one embodiment with no more than about 100 carbon atoms, in another embodiment with no more than about 60 carbon atoms, and in yet another embodiment with no more than about 30 carbon atoms, although the number of carbon atoms can be outside of these ranges, wherein the substituents on the substituted alkyl, aryl, arylalkyl, and alkylaryl groups can be (but are not limited to) halogen atoms, ether groups, aldehyde groups, ketone groups, ester groups, amide groups, carbonyl groups, thiocarbonyl groups, sulfate groups, sulfonate groups, sulfonic acid groups, sulfide groups, sulfoxide groups, phosphine groups, phosphonium groups, phosphate groups, nitrile groups, mercapto groups, nitro groups, nitroso groups, sulfone groups, acyl groups, acid anhydride groups, azide groups, azo groups, cyanato groups, isocyanato groups, thiocyanato groups, isothiocyanato groups, carboxylate groups, carboxylic acid groups, urethane groups, urea groups, mixtures thereof, and the like, wherein two or more substituents can be joined together to form a ring.

In specific embodiments, the gellant is a compound of one of the following formulas:

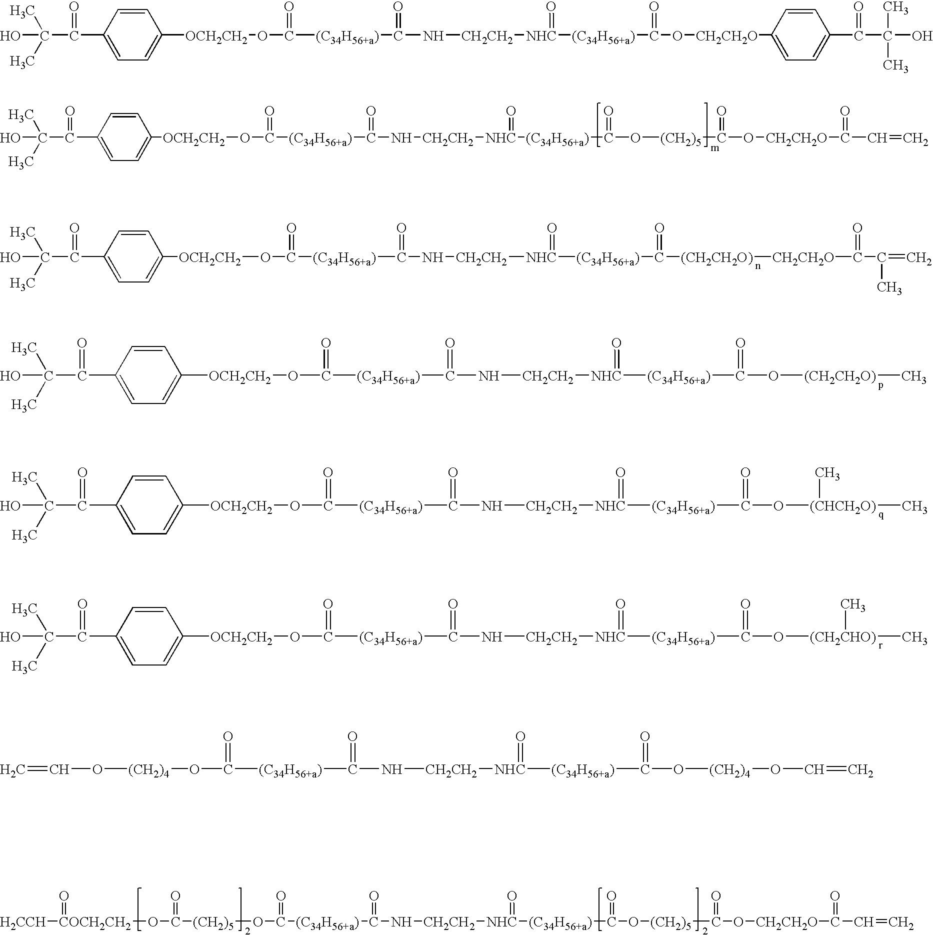

wherein —C₃₄H₅₆₊ₐ— represents a branched alkylene group which may include unsaturated groups and cyclic groups, wherein a is an integer from 0 to 12, and wherein m, n, p, q, and r are each independently an integer from 2 to 5. In particular embodiments, the —C₃₄H₅₆₊ₐ— moiety has the structure of:

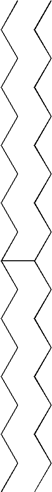

The gellant compounds as disclosed herein can be prepared by any desired or effective method. For example, in one specific embodiment, about two molar equivalents of a diacid of the formula HOOC—R₂—COOH, about one molar equivalent of a diamine of the formula H₂N—R₁—NH₂, and about two molar equivalents of a monoalcohol of the formula R₃—OH can be reacted by use of the coupling agent such as 1,3-dicyclohexylcarbodiimide (DCC) in the presence of a catalyst such as 4-dimethylaminopyridine (DMAP), in the presence of an optional solvent such as methylene chloride (CH₂Cl₂). The ingredients can be mixed together and a one-pot reaction can be employed. More specifically, the diacid, the diamine, and the coupling agent can be mixed together in a first step, and the monoalcohol can be added to the reaction mixture in a second step.

The diacid and the diamine are present in any desired or effective relative amounts, for example in one embodiment at least about 0.4 mole of diamine per every 1 mole of diacid, in another embodiment at least about 0.45 mole of diamine per every 1 mole of diacid, and in yet another embodiment at least about 0.5 mole of diamine per every one mole of diacid, and in one embodiment no more than about 0.57 mole of diamine per every 1 mole of diacid, in another embodiment no more than about 0.53 mole of diamine per every 1 mole of diacid, and in yet another embodiment no more than about 0.51 mole of diamine per every 1 mole of diacid.

The diacid and the monoalcohol are present in any desired or effective relative amounts, in one embodiment at least about 0.75 mole of monoalcohol per every 1 mole of diacid, in another embodiment at least about 0.9 mole of monoalcohol per every 1 mole of diacid, and in yet another embodiment at least about 1 mole of monoalcohol per every one mole of diacid, and in one embodiment no more than about 1.5 moles of monoalcohol per every 1 mole of diacid, in another embodiment no more than about 1.4 moles of monoalcohol per every 1 mole of diacid, and in yet another embodiment no more than about 1.25 moles of monoalcohol per every 1 mole of diacid.

The diamine and the monoalcohol are present in any desired or effective relative amounts, for example in one embodiment at least about 1.5 moles of monoalcohol per every 1 mole of diamine, in another embodiment at least about 1.75 moles of monoalcohol per every 1 mole of diamine, and in yet another embodiment at least about 2 moles of monoalcohol per every one mole of diamine, and in one embodiment no more than about 2.5 moles of monoalcohol per every 1 mole of diamine, in another embodiment no more than about 2.4 moles of monoalcohol per every 1 mole of diamine, and in yet another embodiment no more than about 2.25 moles of monoalcohol per every 1 mole of diamine.

Other exemplary coupling agents include 1,3-dicyclohexylcarbodiimide (DCC), 1-[3-(dimethylamino)propyl]3-ethylcarbodiimide HCl (EDCI), N,N-carbonyldiimidazole, N-cyclohexyl-N′-(2-morpholinoethyl)-carbodiimide methyl-p-toluenesulfonate, (benzotriazol-1-yloxy)tris(dimethylamino)phosphonium hexafluorophosphate (BOP), (o-benzotriazol-1-yl)-N,N,N′,N′-bis(tetramethlylene)uronium hexafluorophosphate (HBTU), bis(2-oxo-3-oxazolidinyl)phosphonic chloride (BOP-Cl), (1H-1,23-benzotriazol-1-yloxy)tris(pyrrolidino)phosphonium hexafluorophosphate (PyBOP), and the like, as well as mixtures thereof.

Other exemplary catalysts include 4-dimethylaminopyridine (DMAP), triethylamine, 1,8-diazabicyclo[5.4.0]undec-7-ene (DBU), and the like, as well as mixtures thereof.

Other exemplary solvents include methylene chloride, tetrahydrofuran, methyl ethyl ketone, toluene, dimethyl formamide, diethyl ether, hexane, ethyl acetate, and the like, as well as mixtures thereof.

The coupling agent and the diacid are present in any desired or effective relative amounts, for example in one embodiment at least about 0.4 mole of diacid per every 1 mole of coupling agent, in another embodiment at least about 0.45 mole of diacid per every 1 mole of coupling agent, and in yet another embodiment at least about 0.5 mole of diacid per every one mole of coupling agent, and in one embodiment no more than about 0.57 mole of diacid per every 1 mole of coupling agent, in another embodiment no more than about 0.53 mole of diacid per every 1 mole of coupling agent, and in yet another embodiment no more than about 0.51 mole of diacid per every 1 mole of coupling agent.

The catalyst and the diacid are present in any desired or effective relative amounts, for example in one embodiment at least about 0.05 mole of catalyst per every 1 mole of diacid, in another embodiment at least about 0.1 mole of catalyst per every 1 mole of diacid, and in yet another embodiment at least about 0.2 mole of catalyst per every one mole of diacid, and in one embodiment no more than about 1 mole of catalyst per every 1 mole of diacid, in another embodiment no more than about 0.8 mole of catalyst per every 1 mole of diacid, and in yet another embodiment no more than about 0.5 mole of catalyst per every 1 mole of diacid.

When the optional solvent is employed, the solvent can be present in any desired or effective amount, for example in one embodiment at least about 30 grams of diacid per liter of solvent, in another embodiment at least about 40 grams of diacid per liter of solvent and in yet another embodiment at least about 50 grams of diacid per liter of solvent, and in one embodiment no more than about 150 grams of diacid per liter of solvent in another embodiment no more than about 125 grams of diacid per liter of solvent, and in yet another embodiment no more than about 1100 grams of diacid per liter of solvent.

The reaction between the diacid and the diamine in the first step of the reaction can be carried out at any desired or effective temperature, for example in one embodiment at least about −5° C., in another embodiment at least about −2.50° C., and in yet another embodiment at least about 0° C., and one embodiment no more than about 2° C., in another embodiment no more than about 10° C., and in yet another embodiment no more than about 5° C. Thereafter, the reaction product of the diacid and diamine can be reacted with the monoalcohol at any desired or effective temperature, for example in one embodiment at least about 15° C., in another embodiment at least about 20° C., and in yet another embodiment at least about 25° C., and one embodiment no more than about 45° C., in another embodiment no more than about 35° C., and in yet another embodiment no more than about 30° C.

The reaction between the diacid, the diamine, and the monoalcohol can be carried out for any desired or effective period of time, for example in one embodiment from about 1 hour to about 11 hours, in another embodiment from about 2 hours to about 7 hours, and in yet another embodiment from about 4 hours to about 5 hours.

Subsequent to completion of the reaction, the product can be isolated by filtration of any solid by-products, or by washing the solution with water depending on the activating agent used. The solvent can be removed by rotary evaporation. If needed, the product can be purified by washing with acetone and drying.

The gellant compounds as disclosed herein can also be prepared by first reacting about two molar equivalents of a diacid of the formula HOOC—R₂—COOH and about one molar equivalent of a diamine of the formula H₂N—R₁—NH₂ under neat conditions (that is, in the absence of a solvent) at elevated temperatures while removing water from the reaction mixture to form an acid-terminated oligoamide. Thereafter, the acid-terminated oligoamide thus formed can be reacted with about 2 molar equivalents of a monoalcohol of the formula R₃—OH by use of a coupling agent such as 1,3-dicyclohexylcarbodiimide (DCC) in the presence of a catalyst such as 4-dimethylaminopyridine (DMAP) in the presence of a solvent such as methylene chloride (CH₂Cl₂) at reduced temperatures.

The diacid and the diamine are present in any desired or effective relative amounts, for example in one embodiment at least about 0.75 mole of diamine per every 2 moles of diacid, in another embodiment at least about 0.85 mole of diamine per every 2 moles of diacid, and in yet another embodiment at least about 1 mole of diamine per every 2 moles of diacid, and in one embodiment no more than about 1.5 moles of diamine per every 2 moles of diacid, in another embodiment no more than about 1.35 moles of diamine per every 2 moles of diacid, and in yet another embodiment no more than about 1.25 moles of diamine per every 2 moles of diacid.

Water can be removed from the reaction mixture between the diacid and the diamine by any desired or effective method, such as by a Dean-Stark trap, molecular sieves or other drying agents, or the like.

The reaction between the diacid and the diamine generally is run neat, although a solvent can be used if desired.

The reaction between the diacid and the diamine can be carried out at any desired or effective temperature, for example in one embodiment from about 130° C. to about 180° C., in another embodiment from about 140° C. to about 175° C., and in yet another embodiment from about 155° C. to about 165° C.

The reaction between the diacid and the diamine can be carried out for any desired or effective period of time, for example in one embodiment from about 1 hour to about 7 hours, in another embodiment from about 2 hours to about 5 hours, and in yet another embodiment from about 3 hours to about 4 hours.

Thereafter, the acid-terminated oligoamide intermediate and the monoalcohol are reacted in the presence of a coupling agent, a catalyst, and a solvent.

The acid-terminated oligoamide intermediate and the monoalcohol are present in any desired or effective relative amounts, for example in one embodiment at least about 2 moles of monoalcohol per every 1 mole of acid-terminated oligoamide intermediate, in another embodiment at least about 2.15 moles of monoalcohol per every 1 mole of acid-terminated oligoamide intermediate, and in yet another embodiment at least about 2.25 moles of monoalcohol per every one mole of acid-terminated oligoamide intermediate, and in one embodiment no more than about 3 moles of monoalcohol per every 1 mole of acid-terminated oligoamide intermediate, in another embodiment no more than about 2.5 moles of monoalcohol per every 1 mole of acid-terminated oligoamide intermediate, and in yet another embodiment no more than about 2.4 moles of monoalcohol per every 1 mole of acid-terminated oligoamide intermediate.

The acid-terminated oligoamide and the coupling agent are present in any desired or effective relative amounts, for example in one embodiment at least about 1.8 moles of coupling agent per every 1 mole of diacid diamide, in another embodiment at least about 2 moles of coupling agent per every 1 mole of diacid diamide, and in yet another embodiment at least about 2.2 moles of coupling agent per every one mole of diacid diamide, and in one embodiment no more than about 3 moles of coupling agent per every 1 mole of diacid diamide, in another embodiment no more that about 2.8 moles of coupling agent per every 1 mole of diacid diamide, and in yet another embodiment no more than about 2.5 moles of coupling agent per every 1 mole of diacid diamide.

The catalyst and the acid-terminated oligoamide intermediate are present in any desired or effective relative amounts, for example in one embodiment at least about 0.05 mole of catalyst per every 1 mole of acid-terminated oligoamide intermediate, in another embodiment at least about 0.1 moles of catalyst per every 1 mole of acid-terminated oligoamide intermediate, and in yet another embodiment at least about 0.2 mole of catalyst per every one mole of acid-terminated oligoamide intermediate, and in one embodiment no more than about 1 mole of catalyst per every 1 mole of acid-terminated oligoamide intermediate, in another embodiment no more than about 0.8 mole of catalyst per every 1 mole of acid-terminated oligoamide intermediate, and in yet another embodiment no more than about 0.5 mole of catalyst per every 1 mole of acid-terminated oligoamide intermediate.

The solvent can be present in any desired or effective amount, for example in one embodiment from about 20 milliliters of solvent per gram of acid-terminated oligoamide intermediate to about 100 milliliters of solvent per gram of acid-terminated oligoamide intermediate, in another embodiment from about 20 milliliters of solvent per gram of acid-terminated oligoamide intermediate to about 90 milliliters of solvent per gram of acid-terminated oligoamide intermediate, and in yet another embodiment from about 30 milliliters of solvent per gram of acid-terminated oligoamide intermediate to about 80 milliliters of solvent per gram of acid-terminated oligoamide intermediate.

The reaction between the acid-terminated oligoamide intermediate, the monoalcohol, and the coupling agent can be carried out at any desired or effective temperature, for example in one embodiment from about 10° C. to about 60° C., in another embodiment from about 15° C. to 40° C., in yet another embodiment from about 20° C. to 35° C.

The reaction between the acid-terminated oligoamide intermediate, the monoalcohol, and the coupling agent can be carried out for any desired or effective period of time, for example in one embodiment from about 1 hour to about 7 hours, in another embodiment from about 2 hours to about 7 hours, and in yet another embodiment from about 2 hours to about 5 hours, and in one embodiment no more than about 3 hours, and in another embodiment no more than about 4 hours.

Subsequent to completion of the reaction, the product can be recovered by any desired or effective method, such as filtration of any solid by-products or washing the solution with water depending on the coupling agent used. The solvent can be removed by rotary evaporation. If needed, the product can be purified by washing with acetone and dried in a vacuum oven.

Analogous procedures can be employed using amine compounds of the formula HNR₃R₄ in place of monoalcohols of the formula R₃OH.

Many embodiments of the compounds thus prepared can exhibit gel-like behavior in that they undergo a relatively sharp increase in viscosity over a relatively narrow temperature range when dissolved in a liquid carrier such as those compounds that behave as curable monomers when exposed to radiation such as ultraviolet light. One example of such a liquid carrier is a propoxylated neopentyl glycol diacrylate such as SR9003, commercially available from Sartomer Co. Inc. In embodiments, some compounds as disclosed herein undergo a change in viscosity of, for example, at least about 10³ centipoise, in further embodiments at least about 10⁵ centipoise, and in yet further embodiments at least about 10⁶ centipoise over a temperature range of, for example, in one embodiment at least about 30° C., in another embodiment at least about 10° C., and in yet another embodiment at least about 5° C., and compounds that do not undergo changes within these ranges are also included herein.

The curable inks disclosed herein may form a semi-solid gel at a first temperature. For example, when the gellant is incorporated into a phase change ink, this temperature is below the specific temperature at which the ink is jetted. The semi-solid gel phase is a physical gel that exists as a dynamic equilibrium comprising one or more solid gellant molecules and a liquid solvent. The semi-solid gel phase is a dynamic networked assembly of molecular components held together by non-covalent interactions such as hydrogen bonding, Van der Waals interactions, aromatic non-bonding interactions, ionic or coordination bonding, London dispersion forces, or the like, which, upon stimulation by physical forces, such as temperature, mechanical agitation, or the like, or chemical forces, such as pH, ionic strength, or the like, can undergo reversible transitions from liquid to semi-solid state at the macroscopic level. The solutions containing the gellant molecules exhibit a thermally reversible transition between the semi-solid gel state and the liquid state when the temperature is varied above or below the gel point of the solution. This reversible cycle of transitioning between semi-solid gel phase and liquid phase can be repeated many times in the solution formulation.

The ink compositions can include the gellant in any suitable amount, such as about 1% to about 50% by weight of the ink. In embodiments, the gellant can be present in an amount of about 2% to about 20% by weight of the ink, such as about 5% to about 15% by weight of the ink, although the value can also be outside of this range.

The gellant compositions disclosed herein can, in at least some embodiments, act as an organic gellant in the ink to the viscosity of the ink within a desired temperature range. In particular, the gellant can in some embodiments form a semi-solid gel in the ink vehicle at temperatures below the specific temperature at which the ink is jetted.

Optionally, a curable wax may be added to the ink formulation. The curable wax may be any wax component that is miscible with the other components and that will polymerize with the curable monomer to form a polymer. The term “wax” includes, for example, any of the various natural, modified natural, and synthetic materials commonly referred to as waxes. A wax is solid at room temperature, specifically at 25° C. Inclusion of the wax promotes an increase in viscosity of the ink as it cools from the jetting temperature.

Suitable examples of curable waxes include, but are not limited to, those waxes that include or are functionalized with curable groups. The curable groups may include, for example, acrylate, methacrylate, alkene, allylic ether, epoxide, oxetane, and the like. These waxes can be synthesized by the reaction of a wax equipped with a transformable functional group, such as carboxylic acid or hydroxyl.

Suitable examples of hydroxyl-terminated polyethylene waxes that may be functionalized with a curable group include, but are not limited to, mixtures of carbon chains with the structure CH₃—(CH₂)ₙ—CH₂OH, where there is a mixture of chain lengths, n, where the average chain length can be in the range of about 16 to about 50, and linear low molecular weight polyethylene, of similar average chain length. Suitable examples of such waxes include, but are not limited to, the UNILIN® series of materials such as UNILIN® 350, UNILIN® 425, UNILIN® 550 and UNILIN® 700 with Mn approximately equal to 375, 460, 550 and 700 g/mol, respectively. All of these waxes are commercially available from Baker-Petrolite. Guerbet alcohols, characterized as 2,2-dialkyl-1-ethanols, are also suitable compounds. Exemplary Guerbet alcohols include those containing about 16 to about 36 carbons, many of which are commercially available from Jarchem Industries Inc., Newark, N.J. PRIPOL® 2033 (C-36 dimer diol mixture including isomers of the formula

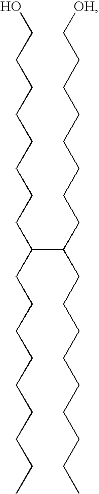

as well as other branched isomers that may include unsaturations and cyclic groups, available from Uniqema, New Castle, Del.; further information on C₃₆ dimer diols of this type is disclosed in, for example, “Dimer Acids,” Kirk-Othmer Encyclopedia of Chemical Technology, Vol. 8, 4^{th} Ed. (1992), pp. 223 to 237, the disclosure of which is totally incorporated herein by reference, can also be used. These alcohols can be reacted with carboxylic acids equipped with UV curable moieties to form reactive esters. Examples of these acids include acrylic and methacrylic acids, available from Sigma-Aldrich Co. In embodiments, suitable curable monomers include waxy acrylates, such as acrylates of UNILIN® 350, UNILIN® 425, UNILIN® 550 and UNILIN® 700.

Suitable examples of carboxylic acid-terminated polyethylene waxes that may be functionalized with a curable group include mixtures of carbon chains with the structure CH₃—(CH₂)ₙ—COOH, where there is a mixture of chain lengths, n, where the average chain length is about 16 to about 50, and linear low molecular weight polyethylene, of similar average chain length. Suitable examples of such waxes include, but are not limited to, UNICID® 350, UNICID® 425, UNICID® 550 and UNICID® 700 with Mn equal to approximately 390, 475, 565 and 720 g/mol, respectively. Other suitable waxes have a structure CH₃—(CH₂)ₙ—COOH, such as hexadecanoic or palmitic acid with n=14, heptadecanoic or margaric or daturic acid with n=15, octadecanoic or stearic acid with n=16, eicosanoic or arachidic acid with n=18, docosanoic or behenic acid with n=20, tetracosanoic or lignoceric acid with n=22, hexacosanoic or cerotic acid with n=24, heptacosanoic or carboceric acid with n=25, octacosanoic or montanic acid with n=26, triacontanoic or melissic acid with n=28, dotriacontanoic or lacceroic acid with n=30, tritriacontanoic or ceromelissic or psyllic acid, with n=31, tetratriacontanoic or geddic acid with n=32, pentatriacontanoic or ceroplastic acid with n=33. Guerbet acids, characterized as 2,2-dialkyl ethanoic acids, are also suitable compounds. Exemplary Guerbet acids include those containing 16 to 36 carbons, many of which are commercially available from Jarchem Industries Inc., Newark, N.J. PRIPOL® 1009 (C-36 dimer acid mixture including isomers of the formula:

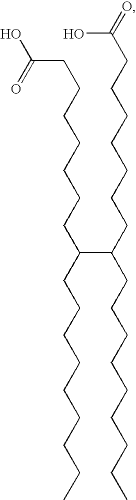

as well as other branched isomers that may include unsaturations and cyclic groups, available from Uniqema, New Castle, Del. Further information on C₃₆ dimer acids of this type is disclosed in, for example, “Dimer Acids,” Kirk-Othmer Encyclopedia of Chemical Technology. Vol. 8, 4^{th} Ed. (1992), pp. 223 to 237, the disclosure of which is totally incorporated herein by reference, can also be used. These carboxylic acids can be reacted with alcohols equipped with UV curable moieties to form reactive esters. Examples of these alcohols include, but are not limited to, 2-allyloxyethanol from Sigma-Aldrich Co.;

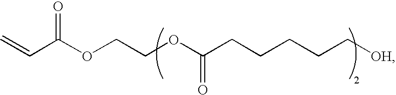

SR495B from Sartomer Company, Inc.;

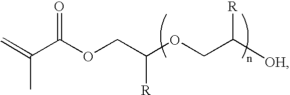

CD572 (R═H, n=10) and SR604 (R=Me, n=4) from Sartomer Company, Inc.

Other suitable examples of curable waxes include, for example, AB₂ diacrylate hydrocarbon compounds that may be prepared by reacting AB₂ molecules with acryloyl halides, and then further reacting with aliphatic long-chain, mono-functional aliphatic compounds. Suitable functional groups useful as A groups in embodiments include carboxylic acid groups and the like. Suitable functional groups useful as B groups in embodiments may be hydroxyl groups, thiol groups, amine groups, amide groups, imide groups, phenol groups, and mixtures thereof. Exemplary AB₂ molecules include, for example, bishydroxy alkyl carboxylic acids (AB₂ molecules in which A is carboxylic acid and B is hydroxyl), 2,2-bis(hydroxymethyl)butyric acid, N,N-bis(hydroxyethyl)glycine, 2,5-dihydroxybenzyl alcohol, 3,5-bis(4-aminophenoxy)benzoic acid, and the like. Exemplary AB₂ molecules also include those disclosed in Jikei et al. (Macromolecules, 33, 6228-6234 (2000)).

In embodiments, the acryloyl halide may be chosen from acryloyl fluoride, acryloyl chloride, acryloyl bromide, and acryloyl iodide, and mixtures thereof. In particular embodiments, the acryloyl halide is acryloyl chloride.

Exemplary methods for making AB₂ molecules may include optionally protecting the B groups first. Methods for protecting groups such as hydroxyls will be known to those of skill in the art. An exemplary method for making AB₂ molecules such as 2,2-bis(hydroxylmethyl)proprionic acid is the use of benzaldehyde dimethyl acetal catalyzed by a sulfonic acid such as p-toluene sulfonic acid in acetone at room temperature to form benzylidene-2,2-bis(oxymethyl)proprionic acid. This protected AB₂ molecule may be subsequently coupled with an aliphatic alcohol Suitable aliphatic alcohols include stearyl alcohol; 1-docosanol; hydroxyl-terminated polyethylene waxes such as mixtures of carbon chains with the stricture CH₃—(CH₂)ₙ—CH₂OH, where there is a mixture of chain lengths, n, having an average chain length, in some embodiments, in the range of about 12 to about 100; and linear low molecular weight polyethylenes that have an average chain length similar to that of the described hydroxyl-terminated polyethylene waxes. Suitable examples of such waxes include, but are not limited to, UNILIN 350, UNILIN 425, UNILIN 550 and UNILIN 700 with Mn approximately equal to 375, 460, 550 and 700 g/mol, respectively. All of these waxes are commercially available from Baker-Petrolite. Guerbet alcohols, characterized as 2,2-dialkyl-1-ethanols, are also suitable compounds. In particular embodiments, the Guerbet alcohols may be chosen from Guerbet alcohols containing 16 to 36 carbon atoms; many such Guerbet alcohols are commercially available from Jarchem Industries Inc., Newark, N.J.

The acid group of the AB₂ monomer may be esterified by the aliphatic alcohol using p-toluenesulfonic acid in refluxing toluene. Following the reaction of the aliphatic alcohol with the protected AB₂ monomer, the protecting groups may be removed in methylene chloride using a palladium carbon catalyst under hydrogen gas. Once deprotected, the final product diacrylate aliphatic ester may be made using acryloyl chloride in methylene chloride with pyridine or triethylamine.

The curable wax can be included in the ink composition in an amount of from, for example, about 0 to about 25% by weight of the ink, such as about 1 or about 2 to about 10 or about 15% by weight of the ink. In an embodiment, the curable wax can be included in the ink composition in an amount of from about 3 to about 10% by weight of the ink, such as about 4 to about 6% by weight of the ink.

Any desired or effective colorant can be employed in the inks, including pigment, dye, mixtures of pigment and dye, mixtures of pigments, mixtures of dyes, and the like, provided that the colorant can be dissolved or dispersed in the ink vehicle. The compositions can be used in combination with conventional ink colorant materials, such as Color Index (C.I.) Solvent Dyes, Disperse Dyes, modified Acid and Direct Dyes, Basic Dyes, Sulphur Dyes, Vat Dyes, and the like.

Examples of suitable dyes include Usharect Blue 86 (Direct Blue 86), available from Ushanti Color; Intralite Turquoise 8GL (Direct Blue 86), available from Classic Dyestuffs; Chemictive Brilliant Red 7BH (Reactive Red 4), available from Chemiequip; Levafix Black EB, available from Bayer; Reactron Red H8B (Reactive Red 31), available from Atlas Dye-Chem; D&C Red #28 (Acid Red 92), available from Warner-Jenkinson; Direct Brilliant Pink B, available from Global Colors; Acid Tartrazine, available from Metrochem Industries; Cartasol Yellow 6GF Clariant; Carta Blue 2GL, available from Clariant; and the like. Particularly suitable are solvent dyes; within the class of solvent dyes, spirit soluble dyes are desired because of their compatibility with the ink vehicles of the present invention. Examples of suitable spirit solvent dyes include Neozapon Red 492 (BASF); Orasol Red G (Ciba); Direct Brilliant Pink B (Global Colors); Aizen Spilon Red C-BH (Hodogaya Chemical); Kayanol Red 3BL (Nippon Kayaku); Spirit Fast Yellow 3G; Aizen Spilon Yellow C-GNH (Hodogaya Chemical); Cartasol Brilliant Yellow 4GF (Clariant); Pergasol Yellow CGP (Ciba); Orasol Black RLP (Ciba); Savinyl Black RLS (Clariant); Morfast Black Conc. A (Rohm and Haas); Orasol Blue GN (Ciba); Savinyl Blue GLS (Sandoz); Luxol Fast Blue MBSN (Pylam); Sevron Blue 5GMF (Classic Dyestuffs); Basacid Blue 750 (BASF), and the like. Neozapon Black X51 [C.I. Solvent Black, C.I. 12195] (BASF), Sudan Blue 670 [C.I. 61554] (BASF), Sudan Yellow 146 [C.I. 12700] (BASF), and Sudan Red 462 [C.I. 260501] (BASF) are particularly suitable in embodiments.

Pigments are also suitable colorants for the inks. Examples of suitable pigments include Violet Paliogen Violet 5100 (BASF); Paliogen Violet 5890 (BASF); Heliogen Green L8730 (BASF); Lithol Scarlet D3700 (BASF); Sunfast® Blue 15:4 (Sun Chemical 249-0592); Hostaperm Blue B2G-D (Clariant); Permanent Red P—F7RK; Hostaperm Violet BL (Clariant); Lithol Scarlet 4440 (BASF); Bon Red C (Dominion Color Company), Oracet Pink RF (Ciba); Paliogen Red 3871 K (BASF); Sunfast® Blue 15:3 (Sun Chemical 249-1284); Paliogen Red 3340 (BASF); Sunfast® Carbazole Violet 23 (Sun Chemical 246-1670); Lithol Fast Scarlet L4300 (BASF); Sunbrite Yellow 17 (Sun Chemical 275-0023); Heliogen Blue L6900, L7020 (BASF); Sunbrite Yellow 74 (Sun Chemical 272-0558); Spectra Pac® C Orange 16 (Sun Chemical 276-3016); Heliogen Blue K6902, K6910 (BASF); Sunfast® Magenta 122 (Sun Chemical 228-0013); Heliogen Blue D6840, D7080 (BASF); Sudan Blue OS (BASF); Neopen Blue FF4012 (BASF); PV Fast Blue B2GO1 (Clariant); Irgalite Blue BCA (Ciba); Paliogen Blue 6470 (BASF); Sudan Orange G (Aldrich), Sudan Orange 220 (BASF); Paliogen Orange 3040 (BASF); Paliogen Yellow 152, 1560 (BASF); Lithol Fast Yellow 0991 K (BASF); Paliotol Yellow 1840 (BASF); Novoperm Yellow FGL (Clariant); Lumogen Yellow D0790 (BASF); Suco-Yellow L1250 (BASF); Suco-Yellow D1355 (BASF); Suco Fast Yellow DI 355, DI 351 (BASF); Hostaperm Pink E 02 (Clariant); Hansa Brilliant Yellow 5GX03 (Clariant); Permanent Yellow GRL 02 (Clariant); Permanent Rubine L6B 05 (Clariant); Fanal Pink D4830 (BASF); Cinquasia Magenta (Du Pont), Paliogen Black L0084 (BASF); Pigment Black K801 (BASF); and carbon blacks such as REGAL 330™. (Cabot), Carbon Black 5250, Carbon Black 5750 (Columbia Chemical), mixtures thereof and the like.

The colorant can be included in the ink in any suitable amount, such as an amount of from about 0.1 to about 15% by weight of the ink, such as about 0.5 or about 1 to about 8 or about 10% by weight of the ink.

In embodiments, the composition further comprises an initiator, such as a photoinitiator, that initiates polymerization of curable components of the ink, including the curable monomer and the optional curable wax. The initiator should be soluble in the composition. In embodiments, the initiator is a UV-activated photoinitiator.

In embodiments, the initiator can be a radical initiator. Examples of radical photoinitiators include (but are not limited to) benzophenone derivatives, benzyl ketones, monomeric hydroxyl ketones, α-amino ketones, acyl phosphine oxides, metallocenes, benzoin ethers, benzil ketals, α-hydroxyalkylphenones, α-aminoalkylphenones, acylphosphine photoinitiators sold under the trade designations of IRGACURE® and DAROCUR® from Ciba, isopropyl thioxanthenones, and the like, and mixtures and combinations thereof. Specific examples include 1-hydroxy-cyclohexylpheny ketone, benzophenone, benzophenone derivatives, 2-benzyl-2-(dimethylamino)-1-(4-(4-morphorlinyl)phenyl)-1-butanone, 2-methyl-1-(4-methylthio)phenyl-2-(4-morphorlinyl)-1-propanone, diphenyl-(2,4,6-trimethylbenzoyl)phosphine oxide, phenyl bis(2,4,6-trimethylbenzoyl)phosphine oxide, benzyl-dimethylketal, isopropylthioxanthone, 2,4,6-trimethylbenzoyldiphenylphosphine oxide (available as BASF LUCIRIN TPO®), 2,4,6-trimethylbenzoylethoxyphenylphosphine oxide (available as BASF LUCIRIN TPO-L®), bis(2,4,6-trimethylbenzoyl)-phenyl-phosphine oxide (available as Ciba IRGACURE® 819) and other acyl phosphines, 2-methyl-1-(4-methylthio)phenyl-2-(4-morphorlinyl)-1-propanone (available as Ciba IRGACURE® 907) and 1-(4-(2-hydroxyethoxy)phenyl)-2-hydroxy-2-methylpropan-1-one (available as Ciba IRGACURE® 2959), 2-benzyl 2-dimethylamino 1-(4-morpholinophenyl)butanone-1 (available as Ciba IRGACURE® 369), 2-hydroxy-1-(4-(4-(2-hydroxy-2-methylpropionyl)-benzyl)-phenyl)-2-methylpropan-1-one (available as Ciba IRGACURE® 127), 2-dimethylamino-2-(4-methylbenzyl)-1-(4-morpholin-4-ylphenyl)-butanone (available as Ciba IRGACURE® 379), titanocenes, isopropylthioxanthenones, 1-hydroxy-cyclohexylphenylketone, benzophenone, 2,4,6-trimethylbenzophenone, 4-methylbenzophenone, diphenyl-(2,4,6-trimethylbenzoyl)phosphine oxide, 2,4,6-trimethylbenzoylphenylphosphinic acid ethyl ester, oligo(2-hydroxy-2-methyl-1-(4-(1-methylvinyl)phenyl)propanone), 2-hydroxy-2-methyl-1-phenyl-1-propanone, benzyl-dimethylketal, and the like, as well as mixtures thereof. In an embodiment, the ink contains an α-amino ketone, such as, for example, IRGACURE® 379 (Ciba Specialty Chemicals), 2-hydroxy-1-(4-(4-(2-hydroxy-2-methylpropionyl)-benzyl)-phenyl)-2-methylpropan-1-one, such as, for example, IRGACURE® 127 (Ciba Specialty Chemicals), bis(2,4,6-trimethylbenzoyl)-phenylphosphineoxide, such as, for example, IRGACURE® 819 and 2-isopropyl-9H-thioxanthen-9-one, such as, for example, DAROCUR® ITX (Ciba Specialty Chemicals).

Mention may also be made of amine synergists, i.e., co-initiators that donate a hydrogen atom to a photoinitiator and thereby form a radical species that initiates polymerization (amine synergists can also consume oxygen dissolved in the ink—as oxygen inhibits free radical polymerization its consumption increases the speed of polymerization), such as ethyl-4-dimethylaminobenzoate and 2-ethylhexyl-4-dimethylaminobenzoate.

In other embodiments, the initiator can be a cationic initiator. Examples of suitable cationic photoinitiators include aryidiazonium salts, diaryliodonium salts, triarysulfonium salts, triarylselenonium salts, dialkylphenacylsulfonium salts, triarylsulphoxonium salts and aryloxydiarylsulfonium salts.

Initiators that absorb radiation, for example UV light radiation, to initiate curing of the curable components of the ink may be used. Initiators for inks disclosed herein can absorb radiation at any desired or effective wavelength, for example in one embodiment from about 200 to 600 nanometers, and in one embodiment about 200 to 500 nanometers, and in another embodiment about 200-420 nanometers. Curing of the ink can be effected by exposure of the ink image to actinic radiation for any desired or effective period of time, in one embodiment from about 0.01 second to about 30 seconds, in another embodiment from about 0.01 second to about 15 seconds, and in yet another embodiment from about 0.01 second to about 5 seconds. By curing is meant that the curable compounds in the ink undergo an increase in molecular weight upon exposure to actinic radiation, such as crosslinking, chain lengthening, or the like.

These lists are not exhaustive, and any known photoinitiator that initiates the free radical or cationic reaction upon exposure to a desired wavelength of radiation such as UV light can be used without limitation.

The total amount of initiator included in the ink may be, for example, about 0.5 to about 15%, such as about 1 to about 10%, by weight of the ink.

The radiation curable phase change inks can also optionally contain an antioxidant. The optional antioxidants can protect the images from oxidation and can also protect the ink components from oxidation during the heating portion of the ink preparation process. Specific examples of suitable antioxidant stabilizers include, for example, NAUGARD® 524, NAUGARD® 635, NAUGARD® A, NAUGARD® L-403, and NAUGARD® 959, commercially available from Crompton Corporation, Middlebury, Conn.; IRGANOX® 1010 and IRGASTAB® UV 10, commercially available from Ciba Specialty Chemicals: GENORAD 16 and GENORAD 40) commercially available from Rahn AG, Zurich, Switzerland, and the like, as well as mixtures thereof. When present, the optional antioxidant is present in the ink in any desired or effective amount, for example in one embodiment at least about 0.01 percent by weight of the ink carrier, in another embodiment at least about 0.1 percent by weight of the ink carrier, and in vet another embodiment at least about 1 percent by weight of the ink carrier, and in one embodiment no more than about 20 percent by weight of the ink carrier, in another embodiment no more than about 5 percent by weight of the ink carrier, and in yet another embodiment no more than about 3 percent by weight of the ink carrier.

The radiation curable phase change inks can also, if desired, contain additives to take advantage of the known functionality associated with such additives. Such additives may include, for example, defoamers, slip and leveling agents, pigment dispersants, and the like, as well as mixtures thereof. The inks can also include additional monomeric or polymeric materials as desired.

In particular embodiments, the radiation curable gel based phase change ink is liquid at temperatures greater than about 75° C. At those temperatures, the phase change ink may have a viscosity of less than about 10 to about 20 millipascal-seconds (mPa·s). In other embodiments, the radiation curable gel based phase change ink has a viscosity of no more than about 20 mPa·s at a temperature between about 60° C. and about 100° C. and a viscosity of at least 10⁴ mPa·s at a temperature of about 50° C. or below. In other embodiments, the phase change ink changes its viscosity by a factor of at least 1 over a temperature range of from about 10° C. to about 50° C.

The phase change ink compositions generally have a jetting temperature from about 40° C. to 125° C., in one embodiment from about 50° C. to about 125° C., in another embodiment from about 60° C. to about 120° C., and in yet another embodiment from about 70° C. to about 110° C.

In one specific embodiment, the inks are jetted at low temperatures, in particular at temperatures below about 110° C., in one embodiment from about 40° C. to about 110° C., in another embodiment from about 50° C. to about 110° C., and in yet another embodiment from about 60° C. to about 90° C. At such low jetting temperatures, the conventional use of temperature differential between the jetted ink and the substrate upon which the ink is jetted to effect a rapid phase change in the ink (that is, from liquid to solid) may not be effective. The gellant can thus be used to affect a rapid viscosity increase in the jetted ink upon the substrate. In particular, jetted ink droplets can be pinned into position on the corrugated substrate through the action of a phase change transition in which the ink undergoes a significant viscosity change from a liquid state to a gel state (or semi-solid state).

In some embodiments, the temperature at which the ink forms the gel state is any temperature below the jetting temperature of the ink, in one embodiment any temperature that is about 5° C. or more below the jetting temperature of the ink. In one embodiment, the gel state can be formed as the temperature drops at a temperature of at least about 25° C., and in another embodiment at a temperature of at least about 30° C., and in one embodiment of no more than about 100° C., in another embodiment of no more than about 70° C., and in yet another embodiment of no more than about 50° C., although the temperature can be outside of these ranges. A rapid and large increase in ink viscosity occurs upon cooling from the jetting temperature, at which the ink is in a liquid state, to the gel temperature, at which the ink is in the gel state. The viscosity increase is in one specific embodiment at least a 10^{2.5}-fold increase in viscosity.

The phase change ink compositions can be prepared by any desired or suitable method. For example, the ink ingredients can be mixed together, followed by heating, to a temperature in one embodiment of from about 80° C. to about 120° C., and stirring until a homogeneous ink composition is obtained, followed by cooling the ink to ambient temperature, for example from about 20 to about 25° C. The inks are solid at ambient temperature.

The inks can be employed in apparatus for direct printing ink jet processes and in indirect (offset) printing ink jet applications. Another embodiment disclosed herein is directed to a process which comprises incorporating an ink as disclosed herein into an ink jet printing apparatus, melting the ink, and causing droplets of the melted ink to be ejected in an imagewise pattern onto a recording substrate. A direct printing process is also disclosed in, for example, U.S. Pat. No. 5,195,430, the disclosure of which is totally incorporated herein by reference. Yet another embodiment disclosed herein is directed to a process which comprises incorporating an ink as disclosed herein into an ink jet printing apparatus, melting the ink, causing droplets of the melted ink to be ejected in an imagewise pattern onto an intermediate transfer member, and transferring the ink in the imagewise pattern from the intermediate transfer member to a final recording substrate. In a specific embodiment, the intermediate transfer member is heated to a temperature above that of the final recording sheet and below that of the melted ink in the printing apparatus. An offset or indirect printing process is also disclosed in, for example, U.S. Pat. No. 5,389,958, the disclosure of which is totally incorporated herein by reference. In one specific embodiment, the printing apparatus employs a piezoelectric printing process wherein droplets of the ink are caused to be ejected in imagewise pattern by oscillations of piezoelectric vibrating elements. Inks as disclosed herein can also be employed in other hot melt printing processes, such as hot melt acoustic ink jet printing, hot melt thermal ink jet printing, hot melt continuous stream or deflection ink jet printing, and the like. Phase change inks as disclosed herein can also be used in printing processes other than hot melt ink jet printing processes.

Upon deposition onto the corrugated substrate, the radiation curable gel based phase change ink, which was ejected from the inkjet printhead as a liquid, solidifies into a solid on the substrate. The phase transition allows for excellent edge acuity with no line or edge raggedness in the image. This excellent edge acuity can be achieved without the need for any precoating or pretreating, such as UV primer, to first seal the surface of the corrugated substrate prior to deposition of the ink.

As used here, edge acuity refers to the straightness or sharpness of the edge of a line of ink deposited upon a substrate. Edge acuity is affected by the correct placement of the ink droplet, the shape and size of the drop, how well the drops join to create a line with a straight edge, and also the degree to which an ink droplet remains at the location on a substrate upon which it is deposited. Lateral bleed of well deposited drops can cause feathering to degrade the edge acuity of otherwise well formed images. The edge acuity can thereby be reduced when ink bleeds away from the location upon which it is deposited.

Some radiation curable inks rely on free radical polymerization of the monomer in the ink. However, free radical polymerization is inhibited by the presence of oxygen. To increase the curing speed, such inks often require a curing zone that has greatly reduced oxygen content, i.e. inerted, typically with nitrogen. An inerted curing zone is not needed with gel based phase change inks because unlike conventional UV curable inks, phase change inks will not run or bleed along the fibers in the corrugated substrate. This bleeding increases the ink surface area and hence the rate of oxygen absorption, and therefore increases oxygen inhibition. Nitrogen inertion is thus required for the conventional UV inks to reduce the rate of oxygen absorption to enable curing at high throughput. However the phase change ink becomes solidified as a compact film on impingement onto the substrate without bleeding, thereby minimizing surface area and minimizing oxygen absorption. Thus, the gel based phase change inks do not require nitrogen inertion to achieve high throughput curing.

Thus, printing on a corrugated substrate may comprise providing and heating a radiation-curable gel based phase change ink. Heating the phase change ink generally causes the ink to become liquid. The ink is then deposited from a printhead onto a corrugated substrate to form the desired image. Upon deposition, the ink solidifies on the substrate (due to the difference in temperature, which causes a phase change back to solid). Finally, the ink is cured in the ambient atmosphere.

An alternative to curing at ambient temperature is that the phase change ink may be heated to temperatures sufficient to cause the ink to become a liquid. In embodiments, that temperature is generally from about 70° C. to about 95° C. or above. Alternatively, the phase change ink is heated until it attains a low viscosity, such as from about 5 to about 15 millipascal-seconds (mPa·s). The phase change ink may then be cured using any radiation source. Generally, however, the phase change ink is ultraviolet-curable.

A device for printing on a corrugated substrate is also provided. A corrugated substrate may be passed through the device in any one of several forms, such as a flat corrugated sheet, an unfolded (flattened) corrugated box, a folded corrugated box, or other corrugated feedstock. The feedstock may consist of only the corrugated liner, e.g. bleached or unbleached kraft paper, which after printing is then formed with the flutes into a cardboard sheet with the printed liner on the outside. The device may comprise a transport system to move the corrugated substrate or liner. For example, the transport system may be a conveyor belt or a vacuum roller system. The transport system may be configured so as to run corrugated substrate through the device at speeds of 200 feet per minute (fpm) or greater.

The device comprises a printing assembly. The printing assembly is configured to deposit the radiation curable gel based phase change ink upon the corrugated substrate. The printing assembly comprises a heat source and a printhead. The heat source is configured to heat the phase change ink to a liquid state. The printhead ejects or deposits the liquid ink onto the corrugated substrate. In particular, the printhead may be a piezoelectric printhead. Notably, the device is not configured to precoat the corrugated substrate prior to depositing the ink. Such a precoating is not necessary as the phase change ink will not bleed or run on an untreated corrugated substrate.

The device also comprises a curing zone. Located in the curing zone is a radiation source for curing the ink. An example of a radiation source is an ultraviolet light source. In particular, the curing zone does not need to be configured to provide an inert atmosphere, such as with nitrogen. In experiments, the gel based phase change inks have been fully cured at throughput speeds greater than 200 fpm.

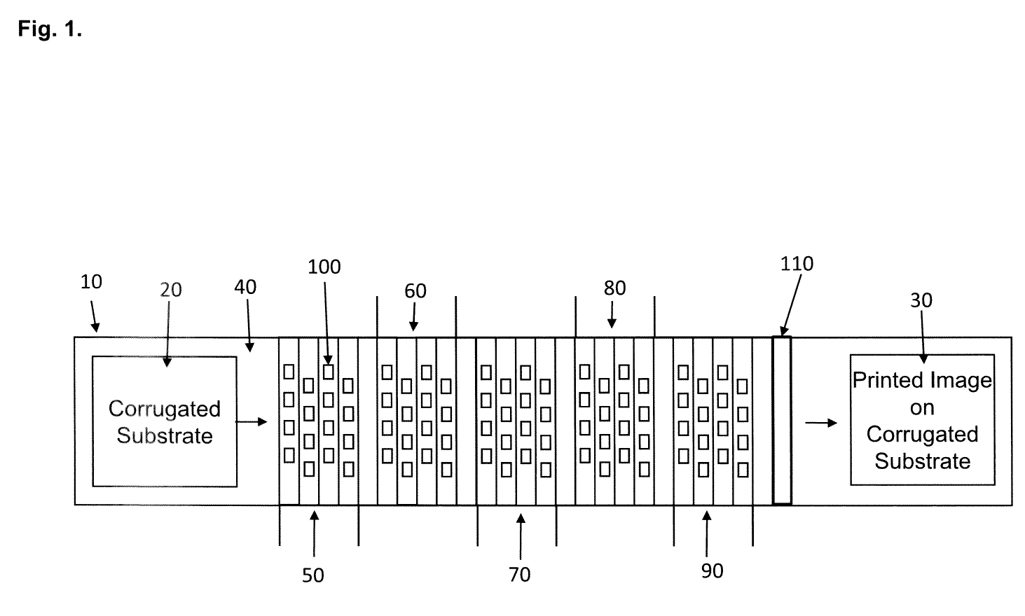

FIG. 1 is one embodiment of a printing system of the present disclosure. The system 10 allows a corrugated substrate 20 to move through several stations and results in a corrugated substrate with a printed image 30. The system 10 includes a transport system, such as conveyor 40, that moves the corrugated substrate. The substrate 20 moves through a printing assembly which prints an image onto the substrate. Here, the assembly has five color zones 50, 60, 70, 80, 90 which print white, magenta, yellow, cyan, and black ink, respectively. Located in each color zone are printheads 100 which eject or deposit the ink onto the substrate. The substrate then passes through curing zone 110 which contains a radiation source for curing the ink.

The devices and methods of the present disclosure are useful in several imaging applications. Those applications include: (1) coding, wherein a single alphanumeric identifier is printed onto a substrate; (2) bar coding, using industry standard barcodes (such as UPC); (3) imprinting, or the printing of repetitive multi-line alphanumeric characters (e.g., an ingredient list); (4) labeling, or the replacement of an affixed label by printing the content of the label directly onto the substrate; (5) replacement printing, or the printing of images that are usually done with analog technologies such as flexographic, gravure, or lithographic printing; (6) imaging, or the printing of non-alphanumeric graphics (such as logos); (7) graphics, which use continuous tones or half tones to reproduce an image; (8) spot coloring, or single colors printed for highlight or background purposes; (9) proofing, a prepared representation of an expected finished product; and (10) point-of-sale imaging done at the delivery, sale, or consumption point of a package. Some of these applications may overlap and are not mutually exclusive.

The following examples are for purposes of further illustrating the present disclosure. The examples are merely illustrative and are not intended to limit devices made in accordance with the disclosure to the materials, conditions, or process parameters set forth therein. All parts are percentages by volume unless otherwise indicated.

### EXAMPLES

### Example 1

The ultraviolet-curable gel based phase change ink was formulated as follows: an amide gellant (16.88 g), Unilin 350-acrylate (prefiltered to 2 μm, 11.25 g), propoxylated neopentyl glycol diacrylate (142.88 g, SR9003, obtained from Sartomer Co. Inc., Exton, Pa.), 2-dimethylamino-2-(4-methylbenzyl)-1-(4-morpholin-4-ylphenyl)-butanone (6.75 g, IRGACURE® 379, obtained from Ciba Specialty Chemicals, Tarrytown, N.Y.), isopropyl-9H-thioxanthen-9-one (4.50 g, DAROCUR® ITX, obtained from Ciba Specialty Chemicals, Tarrytown, N.Y.), bis(2,4,6-trimethylbenzoyl)-phenyl-phosphine oxide (2.25 g, IRGACURE® 819, obtained from Ciba Specialty Chemicals, Tarrytown, N.Y.), 2-hydroxy-1-(4-(4-(2-hydroxy-2-methylpropionyl)-benzyl)-phenyl)-2-methylpropan-1-one (7.88 g, IRGACURE® 127, obtained from Ciba Specialty Chemicals, Tarrytown, N.Y.), and IRGASTAB® UV10 (0.45 g, obtained from Ciba Specialty Chemicals, Tarrytown, N.Y.) were stirred at 90° C. for 2 hours, after which time the solutions were filtered to 0.22 micrometers at 85° C. The resulting solution was added to a stirring solution of magenta pigment dispersion (32.18 g, 21 wt % pigment), also at 90° C., and the resulting ink was stirred for 2 hours at 90° C. The ink was filtered to 6 micrometers at 85° C.

### Example 2

The ink of Example 1 was printed on a variety of media. The print samples were then evaluated subjectively for quality of the text (printed in 8 point font), edge, and line. They were also evaluated objectively using the PIAS II™ system available from Quality Engineering Associates Inc, for edge raggedness and line width. As benchmarks, some other systems were used to make print samples as well. See Table 1 for the tests and comments. In addition, Table 1 lists the Figures corresponding to images of the text, line, and edge for each printing system and media type.

Several media types were printed upon. Brown corrugated cardboard was from a generic shipping box with a single fluted corrugation sheet encased between flat liners of variable coarse fiber dimensions and a surface height variability of approximately 0.1 mm. White corrugated cardboard was from a Xerox cut sheet paper shipping box with a single fluted corrugation sheet encased between flat liners. The surface liner had a thin bonded bleached fiber layer and a surface height variability of approximately 0.1 mm. Super glossy paper was Xerox Digital Color Super Gloss (160 gsm) polymer coated paper. The transparent sheet was Xerox Laser/Copier Transparency clear plastic cut sheet. Plain office paper was Xerox 4200 (75 gsm) laser/copier paper.

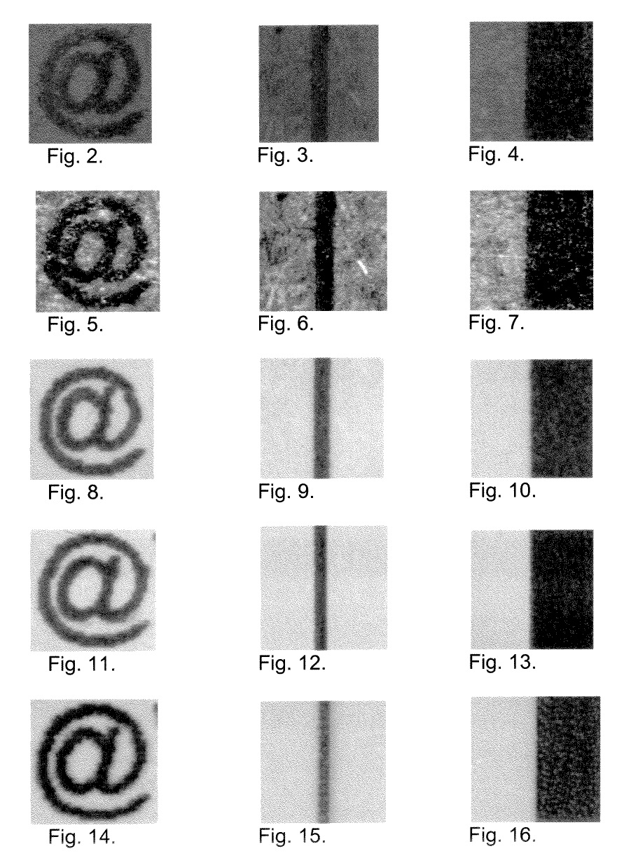

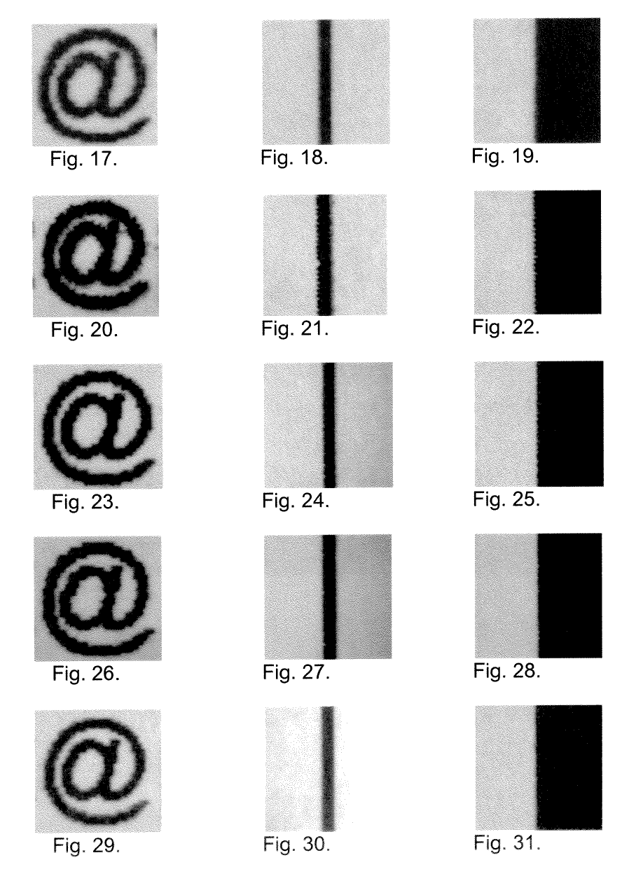

TABLE 1

| | | | | PIAS | | | |
|---|---|---|---|---|---|---|---|
| Printing | | | PIAS Edge | Line | Text | Line | Edge |
| System | Media Type | Subjective Evaluation | Raggedness | Width | Figure | Figure | Figure |
| UV Gel | Brown | No bleeding along the | 0.018 | 0.352 | 2 | 3 | 4 |
| Ink | corrugated | edge. The text is well | | | | | |
| | cardboard | defined and legible. The | | | | | |
| | | high number in edge | | | | | |
| | | raggedness is due to the | | | | | |
| | | low contrast of the | | | | | |
| | | captured image along with | | | | | |
| | | the blemishes present on | | | | | |
| | | brown cardboard which | | | | | |
| | | challenges the | | | | | |
| | | measurement system to | | | | | |
| | | identify the true edge. | | | | | |
| | | Visually, the edges of text, | | | | | |
| | | line, and patch are all well | | | | | |
| | | defined, and there is no | | | | | |
| | | sign of ink bleeding. | | | | | |
| UV Gel | Brown | Same as FIGS. 2-4, but | | | 5 | 6 | 7 |
| Ink | corrugated | digitally manipulated for | | | | | |
| | cardboard | high contrast. | | | | | |
| UV Gel | White | Sharp edges, well defined | 0.007 | 0.37 | 8 | 9 | 10 |
| Ink | corrugated | lines, and text. No ink | | | | | |
| | cardboard | bleeding. | | | | | |
| UV Gel | Digital Color | Very sharp edge. Due to | 0.005 | 0.368 | 11 | 12 | 13 |
| Ink | Super Gloss | glossy media. Some | | | | | |
| | paper, | sputtering of ink on the | | | | | |
| | 160 gsm | curves of text is due to | | | | | |
| | | printhead performance | | | | | |
| | | and not ink bleeding. | | | | | |
| UV Gel | Laser/copier | Sharp edges and well | 0.002 | 0.322 | 14 | 15 | 16 |
| Ink | transparency | defined lines and text. | | | | | |
| UV Gel | Plain office | Sharp edges and well | 0.005 | 0.378 | 17 | 18 | 19 |
| Ink | paper, 75 gsm | defined lines and text. | | | | | |
| first | Cascade | There is bleeding of ink | 0.018 | 0.465 | 20 | 21 | 22 |
| aqueous | paper, 60 gsm | into paper fibers starting to | | | | | |
| ink (TIJ) | | damage the integrity of the | | | | | |
| | | text. The edges are | | | | | |
| | | ragged; the edge | | | | | |
| | | raggedness is larger, and | | | | | |
| | | the line width is larger due | | | | | |
| | | to ink bleeding. | | | | | |
| second | Cascade | The edges, text, and line | 0.005 | 0.361 | 23 | 24 | 25 |
| aqueous | paper, 60 gsm | quality are comparable to | | | | | |
| ink (TIJ) | | the performance of UV-gel | | | | | |
| | | inks on the white | | | | | |
| | | corrugated surface. | | | | | |
| solid wax | Plain office | This print was printed at | 0.006 | 0.355 | 26 | 27 | 28 |
| ink | paper, 75 gsm | the default mode which is | | | | | |
| | | 563 × 400 dpi, and 24 ng | | | | | |
| | | drop mass (which is a | | | | | |
| | | large drop size, and | | | | | |
| | | coarse sampling). Hence | | | | | |
| | | on the edges of the text | | | | | |
| | | one can see the individual | | | | | |
| | | drops. Still the line and | | | | | |
| | | the edge have been | | | | | |
| | | acceptable in the office | | | | | |
| | | market. | | | | | |
| laser | Plain office | The xerographic | 0.003 | 0.358 | 29 | 30 | 31 |
| printer | paper, 75 gsm | performance of edge, line, | | | | | |
| | | and text quality is superior | | | | | |
| | | among all the examples. | | | | | |
| | | Very well defined and | | | | | |
| | | sharp edge and lines, and | | | | | |
| | | well defined text. | | | | | |

Table 1 provides results in terms of edge raggedness and line width. The edge raggedness is measured as the standard deviation from a perfectly straight edge. A lower value indicates better quality. The line width is simply the width of the printed line. The width is measured several times along the length of the line and then averaged. A good line width should be constant, without thicker or thinner sections. The lines referenced in the table are all printed at 600 dpi (563 dpi in the case of solid wax ink) and are all 8 pixels wide (across the width of the line).

Overall, the performance of the UV gel ink on all test media was acceptable. There was no ink bleeding or wicking along the fibers of the media. The text and lines were well defined and legible, even at font size 8. The objective measurement of edge raggedness was almost the same on all media, except for slightly worse performance on brown corrugated cardboard, which can be attributed to the image analysis software, not the quality of the image itself. The line width on all media was comparable, showing the robustness of ink performance.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A method for forming an image on a corrugated substrate comprising:
melting a radiation-curable gel based phase change ink;
depositing at least one drop of the melted ink on the corrugated substrate in a pattern to form an image;
allowing the ink to gel on the substrate; and
curing the ink.

2. The method of claim 1, wherein the ink is cured in an ambient atmosphere.

3. The method of claim 1, wherein the ink is cured by exposing the ink to ultraviolet light.

4. The method of claim 1, wherein the ink is heated until the ink has a viscosity of from about 5 to about 15 millipascal-seconds.

5. The method of claim 1, wherein the ink is heated to a temperature of from about 70° C. to about 95° C.

6. The method of claim 1, wherein the corrugated substrate is not pretreated with ultraviolet-curable-ink primer prior to depositing the at least one drop of the ink.

7. The method of claim 1, wherein the image has an edge raggedness, as measured using the PIAS IQ measurement system, of 0.02 or less.

8. The image on a corrugated substrate formed by the method of claim 1.

9. A method for forming an image on a corrugated substrate comprising:
heating an ultraviolet-curable gel based phase change ink to form a liquid;
depositing one or more droplets of the liquid ink onto a corrugated substrate in an imagewise pattern;
allowing the liquid ink of the imagewise pattern to solidify to form a gel; and
curing the ultraviolet-curable gel ink.

10. The method of claim 9, wherein the ink is cured by exposing the ink to ultraviolet light.

11. The method of claim 9, wherein the ink is heated until the ink has a viscosity of from about 5 to about 15 millipascal-seconds.

12. The method of claim 9, wherein the ink is heated to a temperature of from about 70° C. to about 95° C.

13. The method of claim 9, wherein the corrugated substrate is not pretreated with ultraviolet-curable-ink primer prior to depositing the at least one drop of the ink.

14. The method of claim 9, wherein an image formed by the ink deposit has an edge raggedness, as measured using the PIAS IQ measurement system, of 0.02 or less.

15. The image on a corrugated substrate formed by the method of claim 9.

16. An ultraviolet-curable gel ink printing system comprising:
at least one heat source configured to melt an ultraviolet-curable gel based phase change ink;
at least one printhead configured to deposit one or more droplets of the melted ink in an imagewise pattern onto an associated corrugated substrate; and
an ultraviolet light source configured to cure the ink after the ink is deposited and gelled on the associated corrugated substrate.

17. The printing system of claim 16, wherein the at least one heat source is configured to heat the ink to at least 70° C.

18. The printing system of claim 16, wherein the ultraviolet light source is located in a curing zone that is not configured to provide an inert atmosphere.

19. The printing system of claim 16, wherein the system is not configured to deposit a primer on the associated substrate prior to depositing the ink.

20. The printing system of claim 16, wherein the at least one printhead is a piezoelectric printhead.

21. The printing system of claim 16, wherein the system is configured to fully cure the ink at throughput speeds of 200 feet per minute or greater.
